(19) United States
(12) Patent Application Publication
(10) Pub. No.: US 2022/0222403 A1
(43) Pub. Date: Jul. 14, 2022

(54) Design Method, Design Device, and Program for Regenerator

(71) Applicant: Tokai University Education System, Tokyo (JP)

(72) Inventors: Shinya Hasegawa, Kanagawa (JP); Mariko Senga, Kanagawa (JP)

(21) Appl. No.: 17/596,465

(22) PCT Filed: Jun. 5, 2020
(86) PCT No.: PCT/JP2020/022417

§ 371 Date: Dec. 10, 2021

(30) Foreign Application Priority Data
Jun. 12, 2019 (JP) 2019-109940

(51) Int. Cl. G06F 30/28

(52) U.S. Cl. CPC G06F 30/28

(57) ABSTRACT

A design method for an energy conversion device, the method causing a design device to execute processing comprising: a step of creating an equation showing a thermal efficiency with respect to a predetermined variable including a flow path diameter (equivalent flow path diameter), a frequency, a temperature gradient, and specific acoustic impedance of a flow path in a regenerator performing energy conversion based on an equation of fluid related to the oscillating flow; a step of selecting any one input parameter of the flow path diameter (equivalent flow path diameter), the frequency, the temperature gradient, and the specific acoustic impedance; a step of creating an equation related to the selected parameter based on the equation showing the thermal efficiency and an equation showing a shape of the flow path of the regenerator; and a step of uniquely calculating a value of the selected parameter maximizing the thermal efficiency based on the equation related to the selected parameter by applying a plurality of design values other than the selected parameter related to the energy conversion device which is a design target.

### TECHNICAL FIELD

The present invention relates to a design method, a design device, and a program for a regenerator for providing design support for maximizing a thermal efficiency of the regenerator provided in an energy conversion device using an oscillating flow.

Priority is claimed on Japanese Patent Application No. 2019-109940 filed on Jun. 12, 2019, the content of which is incorporated herein by reference.

### BACKGROUND ART

Various devices such as a Stirling engine, a pulse tube refrigerator, a GM refrigerator, a Stirling cooler, a heat pipe, a thermoacoustic engine that generate electricity from heat, generate cold heat from work, generate cold heat and hot heat from heat, and transport heat by utilizing energy conversion by an oscillating flow have been developed. These energy conversion devices are commonly provided with a pipeline through which a working fluid flows, and a regenerator provided in the middle of the pipeline and to which heat is input. The regenerator is formed of, for example, a porous body having a single to innumerable narrow flow paths and the like. Here, a thermoacoustic phenomenon will be described as one example of the oscillating flows of a fluid.

The thermoacoustic phenomenon in which energy is exchanged between heat and sound waves has been known for a long time. A thermoacoustic engine that uses a thermoacoustic phenomenon applies heat to generate sound waves and uses the sound waves to physically generate electricity, or uses the reverse cycle to generate cold heat and use the cold heat.

In case of heat is applied to the regenerator of the thermoacoustic engine from the outside and a temperature gradient exceeding a threshold is applied in the axial direction of the flow path, sound waves are generated, and energy exchange between a work flow and a heat flow carried by the sound waves propagating in the flow path is performed. In case of the thermoacoustic engine is used, energy can be extracted using waste heat that has not been used so far, so that it is attracting attention as a waste heat regeneration device. As the waste heat regeneration device, for example, a traveling wave thermoacoustic engine in which a solid piston of a Stirling engine is replaced with a sound wave has been achieved. The traveling wave thermoacoustic engine operates according to the principle that the heat flow flows from a high temperature portion to a low temperature portion, while the work flow flows from the low temperature portion to the high temperature portion in the opposite direction, and energy conversion between the heat flow and the work flow is performed in the regenerator.

According to this traveling wave thermoacoustic engine, since an isothermal reversible cycle is essentially achieved, a thermal efficiency approaching the Carnot efficiency can be achieved. In order to achieve an isothermal reversible thermodynamic cycle, it is necessary to form the flow path diameter small so that the temperature applied to the tube wall of the flow path of the regenerator and the temperature of the fluid in the flow path are isothermal. On the other hand, the smaller the flow path diameter, the greater the viscous dissipation generated between the fluid and the tube wall, so that the thermal efficiency is lowered.

Therefore, in the regenerator of the thermoacoustic engine, there is an optimum flow path diameter for maximizing the thermal efficiency. Unique determination of this optimum flow path diameter has not existed in techniques in the related method, and in fact, it was determined by performing numerical calculations and experiments as in the techniques described in the literature shown below.

As a program that can perform simulations on thermoacoustic engines, there is Delta EC published by the Los Alamos Laboratory (Non Patent Document 1), up to now.

In this program, the sound field and output can be calculated by inputting parameters such as the configuration and working fluid to be designed.

Highly efficient thermoacoustic engines reported so far include Backhaus's device in 1999 (Non Patent Document 2) and Tijani's device in 2011 (Non Patent Document 3), which were designed by calculation by the above Delta EC. In Delta EC, the designer inputs the configuration to be manufactured, so that the designer also determines the parameters of the regenerator described above. Therefore, in a case where it is desired to determine the flow path diameter for increasing the thermal efficiency, by repeating the calculation while changing the flow path diameter of the regenerator on the program, the search for the flow path diameter of the regenerator so as to increase the thermal efficiency has been performed.

In addition to using Delta EC, it is also possible to optimize the flow path diameter of the regenerator by performing numerical simulation by creating a program by itself using thermoacoustic theory. For example, in 2010, Ueda and others reported the calculation results of a thermoacoustic refrigerator in which the thermal efficiency was calculated and the parameters were optimized while changing some parameters including the flow path diameter of the regenerator (Non Patent Document 4).

Furthermore, even in recent years, in 2017, a calculation result of optimization while changing the value of the flow path diameter of the regenerator has been reported (Non Patent Document 5). In addition, the optimization of the flow path diameter of the regenerator can be performed experimentally by preparing a plurality of regenerators having different flow path diameters and repeating the experiment of measuring the thermal efficiency for each of regenerators.

### CITATION LIST

### Non Patent Documents

[Non Patent Document 1]

S. Garrett, “DELTAEC is also an acoustics teaching tool”, Acoustics '08 Paris. (Proceedings).

[Non Patent Document 2]

S. Backhaus & G. W. Swift, “A thermoacoustic Stirling heat engine”, Nature volume 399, pages 335-338.

[Non Patent Document 3]

M. E. H. Tijani and S. Spoelstra, “A high performance thermoacoustic engine”, J. Appl. Phys. 110, 093519 (2011).

[Non Patent Document 4]

Y. Ueda, B. M. Mehdi, K. Tsuji, and A. Akisawa, “Optimization of the regenerator of a traveling-wave thermoacoustic refrigerator”, J. Appl. Phys. 107, 034901 (2010).

[Non Patent Document 5]

I. Farikhah and Y. Ueda, “Numerical Calculation of the Performance of a Thermoacoustic System with Engine and Cooler Stacks in a Looped Tube”, Appl. Sci. 2017, 7, 672.

[Non Patent Document 6]

N. Rott, Damped and thermally driven acoustic oscillations in wide and narrow tubes, Journal of Applied Mathematics and Physics (ZAMP), 20, 230-243, (1969).

[Non Patent Document 7]

A. Tominaga, “Thermodynamic aspects of thermoacoustic theory,” Cryogenics 35, 427-440 (1995).

[Non Patent Document 8]

Richard Raspet, William V. Slaton, Craig J. Hickey, and Robert A. Hiller, “Theory of inert gas-condensing vapor thermoacoustics: Propagation equation,” J. Acoust. Soc. Am. 112 (4), 1414-1422 (2002).

[Non Patent Document 9]

William V. Slaton, Richard Raspet, Craig J. Hickey, and Robert A. Hiller, “Theory of inert gas-condensing vapor thermoacoustics: Transport equation,” J. Acoust. Soc. Am. 112 (4), 1423-1430 (2002).

### SUMMARY OF INVENTION

### Technical Problem

As described above, according to the technique in the related method, in a case where the flow path diameter of the regenerator is determined, it is necessary to perform an enormous calculation of searching for the optimum flow path diameter while changing the flow path diameter of the regenerator for one device configuration. Furthermore, each time the conditions for operating the thermoacoustic engine configuration such as the installation position of the regenerator are changed, since the sound field formed at the position of the regenerator also changes, it is necessary to repeatedly calculate the optimum value of the flow path diameter of the regenerator each time.

In addition, in a case of experimentally optimizing the flow path diameter of the regenerator, it is necessary to prepare a plurality of regenerators with different flow path diameters and measure the thermal efficiency, and depending on the device configuration of the thermoacoustic engine, the operating conditions required by the designer may not be met, resulting in enormous cost and development time. Therefore, there is a problem that it is difficult to predict the design of the thermoacoustic engine having the optimum flow path diameter of the regenerator under the ideal operating conditions of the designer.

Hereinbefore, for the sake of clarity, the problems for determining the flow path diameter in the regenerator of a thermoacoustic engine with thermal efficiency at optimized condition have been described. In addition to the flow path diameter, the frequency, the temperature gradient, and the specific acoustic impedance can be considered as parameters for optimizing the thermal efficiency of the regenerator in the energy conversion device using the oscillating flow, not limited to the thermoacoustic engine. As described above for these parameters, it is necessary to perform a huge amount of calculation to search for the optimum parameters while changing these parameters one by one. Furthermore, each time the configuration of the energy conversion device such as the installation position of the regenerator and the conditions to be operated are changed, since the sound field formed at the position of the regenerator also changes, it is necessary to repeatedly calculate the optimum value of the flow path diameter, the frequency, the temperature gradient, and the specific acoustic impedance of the regenerator each time.

In addition, similarly to the case of experimentally optimizing the parameters of the frequency, the temperature gradient, and the specific acoustic impedance other than the flow path diameter of the regenerator, it is necessary to measure the thermal efficiency while changing the conditions one by one, and depending on the configuration of the energy conversion device, the operating conditions required by the designer may not be met, resulting in enormous cost and development time. Therefore, there is a problem that it is difficult to predict the design of the energy conversion device having the optimum parameters of the regenerator under the ideal operating conditions of the designer.

The present invention has been made in view of the above circumstances, and provides a design method, a design device, and an object thereof is to provide a design method, a design device, and a program for providing design support for maximizing thermal efficiency of a regenerator included in an energy conversion device using an oscillating flow.

### Solution to Problem

According to an aspect of the present invention, there is provided a design method for an energy conversion device using an oscillating flow of a working fluid enclosed inside the energy conversion device, the method causing a design device to execute processing including: a step of creating an equation showing a thermal efficiency with respect to a predetermined variable including a flow path diameter (equivalent flow path diameter), a frequency, a temperature gradient, and specific acoustic impedance of a flow path in a regenerator performing energy conversion based on an equation of fluid related to the oscillating flow; a step of selecting any one input parameter of the flow path diameter (equivalent flow path diameter), the frequency, the temperature gradient, and the specific acoustic impedance; a step of creating an equation related to the selected parameter based on the equation showing the thermal efficiency and an equation showing a shape of the flow path of the regenerator; and a step of uniquely calculating a value of the selected parameter maximizing the thermal efficiency based on the equation related to the selected parameter by applying a plurality of design values other than the selected parameter related to the energy conversion device which is a design target.

According to the present invention, based on the equation showing the thermal efficiency of the energy conversion device and the shape of the flow path of the regenerator, the equation for calculating any one of the flow path diameter (equivalent flow path diameter; the description of the equivalent flow path diameter will be described later. Hereinafter, writing with the equivalent flow path diameter will be omitted.), the frequency, the temperature gradient, and the specific acoustic impedance of the regenerator of the energy conversion device is created. Therefore, it is possible to omit a huge amount of calculation such as performing optimization while changing the value of any one of the flow path diameter, the frequency, the temperature gradient, and the specific acoustic impedance of the regenerator, and it is possible to improve the design efficiency and reduce the design cost.

In addition, in the present invention, the equation related to the selected parameter may be a quadratic or higher equation, and the equation related to the selected parameter may be configured to create based on a condition that a derivative obtained by differentiating the quadratic or higher equation with respect to the predetermined variable so as to maximize the thermal efficiency is 0.

According to the present invention, it is possible to create the equation for calculating any one of the flow path diameter, the frequency, the temperature gradient, and the specific acoustic impedance of the regenerator so as to maximize the thermal efficiency. At this time, in a case where the equation is a cubic or higher equation, depending on the equation of the fluid to be used or the parameter to be selected, there are a plurality of conditions in which the derivative obtained by differentiation is 0, and the selected parameter may be obtained by selecting the value that maximizes the thermal efficiency.

In addition, in the present invention, the working fluid may be a gas and/or a liquid, and the equation of the fluid may be configured to include an equation related to the gas and/or the liquid.

According to the present invention, even in case of the working gas enclosed in the energy conversion device is a gas or a liquid, or both a gas and a liquid, it is possible to create the equation for calculating any one of the flow path diameter, the frequency, the temperature gradient, and the specific acoustic impedance of the regenerator.

In addition, in the present invention, the equation showing the shape of the flow path may be configured to set as any one of flow paths formed of a circular tube, a parallel plate, a polygon, and a pin array. In addition, in the present invention, the equation showing the shape of the flow path may be configured to set for any one of flow paths formed of a foamed metal, a steel wool, filled metal powders, and a rounded film having irregularities. In addition, in the present invention, the equation showing the shape of the flow path may be configured to set for a flow path formed by laminating thin mesh plates having different flow path diameters (flow path widths), flow path shapes, and thicknesses.

According to the present invention, it is possible to create the equation for calculating any one of the flow path diameter, the frequency, the temperature gradient, and the specific acoustic impedance of a normal circular tube, parallel plate, polygonal, pin array, a random flow path, or a flow path in which pattern is repeated as the shape of the flow path of the regenerator.

In addition, in the present invention, the invention may be configured to further include a step of separating a work source into a component contributing to energy conversion and a component dissipative due to factors including viscosity and heat conduction in the regenerator based on a thermoacoustic theory in the step of creating the equation showing the thermal efficiency; and a step of adding or deleting a component corresponding to the energy conversion device applied by a step of separating a heat flux density into a component associated with energy conversion of the regenerator and a component of heat diffusion generated by the oscillating flow.

According to the present invention, it is possible to easily calculate the equation for calculating any one of the flow path diameter, the frequency, the temperature gradient, and the specific acoustic impedance of the regenerator for the energy conversion device using a thermoacoustic phenomenon.

In addition, in the present invention, the equation of the fluid may be set to an equation related to traveling wave energy conversion.

According to the present invention, it is possible to easily calculate the equation for calculating any one of the flow path diameter, the frequency, the temperature gradient, and the specific acoustic impedance of the regenerator for the energy conversion device using a traveling wave thermoacoustic phenomenon.

In addition, according to another aspect of the present invention, there is provided a design device of an energy conversion device using an oscillating flow of a working fluid enclosed inside the energy conversion device, the device including: an input device configured to perform t input to select any one of the parameters of a flow path diameter (equivalent flow path diameter), a frequency, a temperature gradient, and specific acoustic impedance of a flow path in a regenerator performing energy conversion; and a computation device configured to create an equation showing a thermal efficiency of a predetermined variable including the flow path diameter (equivalent flow path diameter), the frequency, the temperature gradient, and the specific acoustic impedance based on an equation of fluid related to the oscillating flow, creates an equation related to the parameter selected by input of the input device based on the equation showing the thermal efficiency and an equation showing a shape of the flow path of the regenerator; and uniquely calculates a value of the selected parameter maximizing the thermal efficiency based on the equation related to the selected parameter by applying a plurality of design values other than the selected parameter related to the energy conversion device which is a design target.

According to the present invention, it is possible to easily calculate any one of the flow path diameter, the frequency, the temperature gradient, and the specific acoustic impedance of the regenerator simply by inputting the design value according to the configuration of the energy conversion device which is the design target. Compared to the method in the related art that calculates the maximum point of thermal efficiency while changing any one of the flow path diameter, the frequency, the temperature gradient, and the specific acoustic impedance every time the configuration of the energy conversion device changes, the processing required for design can be simplified and the design time can be significantly reduced.

In addition, according to still another aspect of the present invention, there is provided a program executed by a design device of an energy conversion device using an oscillating flow of a working fluid enclosed inside the energy conversion device, the program is configured to cause a computer to: create an equation showing a thermal efficiency with respect to a predetermined variable including a flow path diameter (equivalent flow path diameter), a frequency, a temperature gradient, and specific acoustic impedance of a flow path in a regenerator that performs energy conversion based on an equation of fluid related to the oscillating flow; select any one parameter of the flow path diameter (equivalent flow path diameter), the frequency, the temperature gradient, and the specific acoustic impedance, based on input; create an equation related to the selected parameter based on the equation showing the thermal efficiency and an equation showing a shape of the flow path of the regenerator; and uniquely calculate a value of the selected parameter maximizing the thermal efficiency based on the equation related to the selected parameter by applying a plurality of design values other than the selected parameter related to the energy conversion device which is a design target.

According to the present invention, it is possible to provide a program that executes processing of easily calculating any one of the flow path diameter, the frequency, the temperature gradient, and the specific acoustic impedance of the regenerator simply by inputting the design value that matches the configuration of the energy conversion device which is the design target into the design device. Compared to the method in the related art that calculates the maximum point of thermal efficiency while changing any one of the flow path diameter, the frequency, the temperature gradient, and the specific acoustic impedance every time the configuration of the energy conversion device changes, the processing required for design can be simplified and the design time can be significantly reduced.

### Advantageous Effects of Invention

According to the present invention, it is possible to design the energy conversion device using the oscillating flow that maximizes thermal efficiency.

### BRIEF DESCRIPTION OF DRAWINGS

FIG. 1 is a block diagram showing a configuration of a design device for an energy conversion device according to an embodiment of the present invention.

FIG. 2 is a diagram showing a configuration of a thermoacoustic engine.

FIG. 3 is a diagram showing a configuration of a regenerator.

FIG. 4 is a diagram showing steps of creating an equation for designing an energy conversion device.

FIG. 5 is a diagram showing a flowchart of a design support program for the energy conversion device.

FIG. 6 is a table showing design values used for calculating a flow path diameter of a flow path of the regenerator.

FIG. 7 is a graph showing a calculation result of a circular tube-shaped flow path diameter of a regenerator that maximizes thermal efficiency.

FIG. 8 is a graph showing a calculation result of a flow path diameter of a parallel plate of the regenerator that maximizes the thermal efficiency.

FIG. 9 is a table numerically showing a calculation result of the circular tube-shaped flow path diameter of the regenerator that maximizes the thermal efficiency.

FIG. 10 is a table numerically showing a calculation result of the flow path diameter of the parallel plate of the regenerator that maximizes the thermal efficiency.

### DESCRIPTION OF EMBODIMENTS

Hereinafter, embodiments of the present invention will be described with reference to the drawings. The present invention is a design method, design device, and program for an energy conversion device using an oscillating flow that maximizes thermal efficiency, which have required time to determine in the related method.

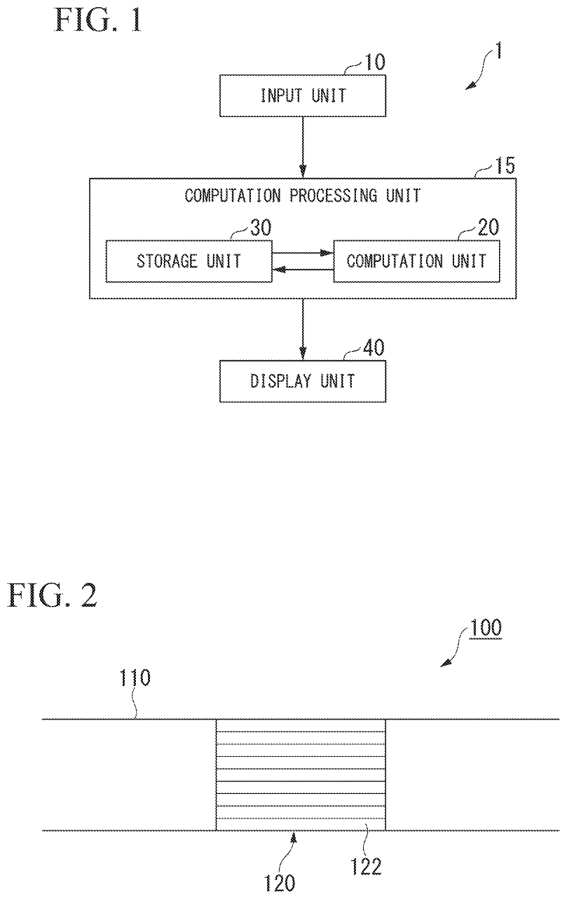

As shown in FIG. 1, a design device 1 of the energy conversion device is provided with an input unit 10 for inputting information by an operator, a computation unit 20 for performing computation processing based on information input from the input unit 10, a storage unit 30 that stores the information necessary for the computation processing of the computation unit 20, and a display unit 40 that outputs a computation result calculated by the computation unit 20. The computation unit 20 and the storage unit 30 are collectively referred to as a computation processing unit 15.

The design device 1 is achieved by, for example, an information terminal device such as a personal computer, a tablet terminal, or a smartphone. The design device 1 may be a server device, acquire information input by the operation of the above information terminal device or the like via a network, perform computation processing, and provide the computation result to these information terminal devices or the like.

The input unit 10 is an interface for inputting information necessary for computation such as a keyboard, a touch panel, a voice input device, and a gesture input device. The operator selects a design target of the energy conversion device (flow path diameter, frequency, temperature gradient, and specific acoustic impedance of regenerator) in the input unit 10, and inputs the design values necessary for the design other than the selected design target. A plurality of flow path diameters, frequencies, temperature gradients, and specific acoustic impedances of the regenerator which is the design target may be independently designed, and necessary design values may be input. The storage unit 30 is a storage device such as an HDD, a flash memory, a RAM, or a read only memory (ROM). The storage unit 30 stores information such as an equations and a parameter used in the computation. The storage unit 30 stores one or more of each equation created for obtaining any one of the flow path diameter, the frequency, the temperature gradient, and the specific acoustic impedance of the regenerator of the energy conversion device as described later.

The computation unit 20 reads out information stored in the storage unit 30 based on the information input by the input unit 10, and performs computation processing for any one of the flow path diameter, the frequency, the temperature gradient, and the specific acoustic impedance of the regenerator included in the energy conversion device described later. Since one or more equations created for obtaining the flow path diameter, the frequency, the temperature gradient, and the specific acoustic impedance of the regenerator are stored, each equation may be calculated independently. The contents of the computation processing of the computation unit 20 will be described later.

The display unit 40 outputs the contents of the computation result of the computation unit 20. As the display unit 40, for example, a display device such as a liquid crystal display, a light emitting diode (LED) display, an organic electro- luminescence (organic EL) display, a digital mirror device, a plasma display, or a projection device is used.

The above-described computation unit 20 is achieved by, for example, a hardware processor such as a CPU executing a program (software). A part or all of these components may be achieved by hardware (circuit portion; including circuitry) such as a large scale integration (LSI), an application specific integrated circuit (ASIC), a field-programmable gate array (FPGA), a graphics processing unit (GPU), or may be achieved by collaboration between software and hardware.

In addition, the program may be stored in advance in a storage device such as a hard disk drive (HDD) or a flash memory, or may be stored in a removable storage medium such as a DVD or a CD-ROM, and may be installed by mounting the storage medium on a drive device. In addition, the computer program may be distributed to a computer via a communication line, and the computer receiving the distribution may execute the program. In addition, a part or all of the programs executed by the computer such as one or more CPUs of the above embodiment can be distributed via a communication line or a computer-readable recording medium.

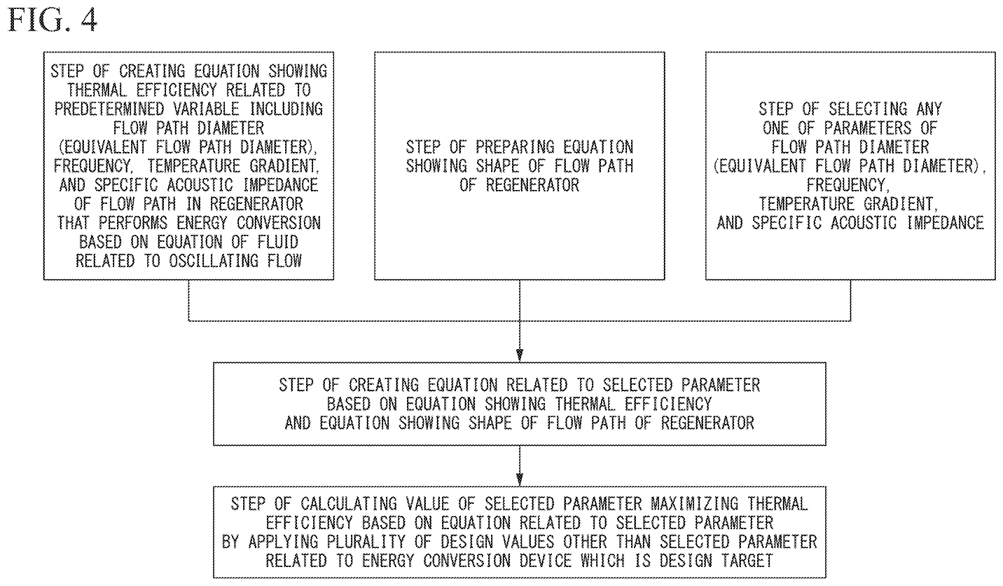

Here, steps of creating equations used in the design device 1 will be described. In order to create an equation, the equation for calculating any one of the flow path diameter, the frequency, the temperature gradient, and the specific acoustic impedance of the regenerator is largely created through a “step of creating the equation showing thermal efficiency related to the predetermined variable including the flow path diameter (equivalent flow path diameter), the frequency, the temperature gradient, and the specific acoustic impedance of the flow path in the regenerator that performs energy conversion based on the equation of the fluid related to the oscillating flow”, a “step of preparing the equation showing the shape of the flow path of the regenerator”, a “step of selecting any one of parameters of the flow path diameter (equivalent flow path diameter), the frequency, the temperature gradient, and the specific acoustic impedance”, a “step of creating the equation related to the selected parameter based on the equation showing thermal efficiency and the equation showing the shape of the flow path of the regenerator”, and a “step of calculating the value of the selected parameter maximizing thermal efficiency based on the equation related to the selected parameter by applying a plurality of design values other than the selected parameter related to the energy conversion device which is the design target” (refer to FIG. 4). The “step of creating the equation showing thermal efficiency related to the predetermined variable including the flow path diameter (equivalent flow path diameter), the frequency, the temperature gradient, and the specific acoustic impedance of the flow path in the regenerator that performs energy conversion based on the equation of the fluid that can describe the oscillating flow”, the “step of preparing the equation showing the shape of the flow path of the regenerator”, and the “step of selecting any one of parameters of the flow path diameter (equivalent flow path diameter), the frequency, the temperature gradient, and the specific acoustic impedance” are not determined in order, and any step may be proceeded.

Next, a design method of an energy conversion device for deriving an equation used for a computation operation executed by the computation unit 20 will be described. Hereinafter, the design of the flow path diameter of the regenerator will be described among the design methods for the thermoacoustic engine, using the thermoacoustic phenomenon as a specific example. The design method of the energy conversion device is not limited to the thermoacoustic engine based on the thermoacoustic phenomenon, and can be applied to an energy conversion device such as a Stirling engine, a pulse tube refrigerator, a GM refrigerator, a Stirling cooler, a heat pipe, a thermoacoustic engine that utilizes an oscillating flow of fluid. In addition to the flow path diameter of the regenerator, any one of the frequency, the temperature gradient, and the specific acoustic impedance can be designed.

As shown in FIG. 2, a traveling wave thermoacoustic engine 100 is provided with a pipeline 110 with working fluid sealed inside, and a regenerator 120 provided in the pipeline. The pipeline 110 is formed in a circular tube shape so that the pipe axis is in the flow line direction of the working fluid, for example. The shape of the pipeline may be, for example, square or triangular as long as the shape is tubular, and is not limited to a circular tube shape. As the working fluid, a gas such as an inert gas made of nitrogen, helium, argon, and a mixed gas of helium and argon, and air, a liquid such as water or alcohol, or a fluid in which both of these gases and liquids are present may be used, and the fluid is not limited to these materials as long as the fluid can transmit an oscillating flow.

One end portion of the regenerator 120 is heated along the flow line direction of the working fluid, and the other end portion is cooled. As a result, the regenerator 120 forms a temperature gradient along the flow line direction of the working fluid. The regenerator 120 forms a temperature gradient between both end portions to generate self-excited vibration of the working gas, and amplifies the sound power generated by the working gas.

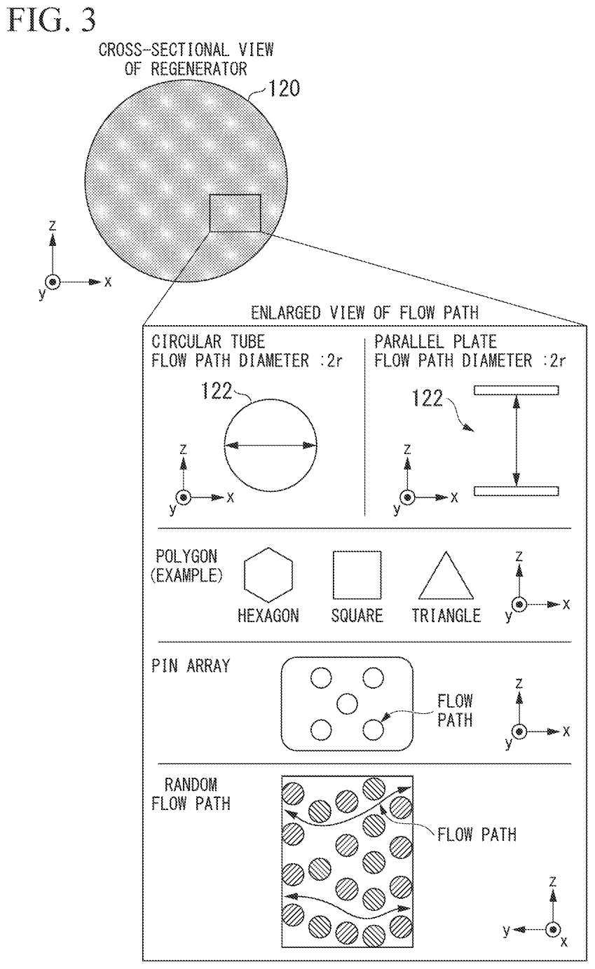

As shown in FIG. 3, the regenerator 120 assumed in this calculation example is provided with one to a plurality of small-diameter flow paths 122. The flow paths 122 are provided in the regenerator 120 from one to innumerable so as to open along the flow line direction of the working fluid. In the regenerator 120, for example, a large number of flow paths 122 are formed by a honeycomb structure made of ceramics or a structure in which a large number of stainless steel thin mesh plates are laminated, but the flow path 122 is not limited to these structures as long as it is a material that forms a fine flow path such as a glass pipe and allows the oscillating flow to pass through. In addition, in addition to the shape formed of foamed metal or steel wool, the flow path 122 may be formed by filling metal powder, rolling a film having irregularities, or combining thin plates having different flow path diameters (flow path widths), flow path shapes, or thicknesses, and can also be applied to an equivalent flow path in the case where the flow path is a random flow path which not uniform or a flow path in which pattern is repeated in the axial direction and the flow path diameter (flow path width) direction in this manner.

The flow path 122 is formed of, for example, a circular tube shape, a parallel plate shape, a polygonal shape, a pin array shape, a random flow path or a flow path in which pattern is repeated. The design method of the thermoacoustic engine 100 according to the present embodiment proposes a method of obtaining an optimum value for the flow path diameter (flow path radius =r) of one flow path 122 of the regenerator 120 of the thermoacoustic engine 100. This design method is not limited to the shapes of the flow paths 122 of the circular tube and the parallel plate illustrated below, and may be applied to other flow path shapes such as a polygon, a pin array, a random flow path or a flow path in which pattern is repeated.

Hereinafter, in the design method of the thermoacoustic engine 100, first, an equation development method and a method of obtaining the flow path diameter of the flow path 122 will be described for the case where the shape of the flow path 122 is a circular tube and the case where the flow path 122 is a parallel plate. In addition, as a calculation example, a calculation example was shown for the case of gas by using the development method based on the thermoacoustic theory of Rott (Non Patent Document 6) and Tominaga (Non Patent Document 7) from the equation of fluid. The above-described development method based on the equation of the fluid or thermoacoustic theory is not indispensable, and in case of it is an equation of fluid, this method can be applied to obtain the optimum flow path diameter of the flow path 122.

### Step of Creating Equation Showing Thermal Efficiency related to Predetermined Variable including Flow Path Diameter (Equivalent Flow Path Diameter), Frequency, Temperature Gradient, and Specific Acoustic Impedance of Flow Path in Regenerator that Performs Energy Conversion based on Equation of Fluid Related to Oscillating Flow

Here, the equation of the fluid is used to express the thermal efficiency η of the thermoacoustic engine 100 by an equation. Here, as the equation of the fluid, the continuity equation of Equation (1), the Navier-Stokes equation of Equation (2), the energy equation of Equation (3), and the state equation of Equation (4) are used as examples, but the equation of the fluid is not limited to the following equation as long as it is possible to express the thermal efficiency η of the thermoacoustic engine 100. In addition, in a case where a liquid is used as other working fluid, or in a case where both liquid and gas are included, an equation of the fluid such as the equation related to liquid corresponding to the working gas of the device to be designed or the equation related to gas and liquid may be used, and is not limited to the following equation.

$$\begin{matrix}[ Math . 1 ] & \\ \frac{D ρ}{Dt} + ρ ∇ \cdot u = 0 & ( 1 ) \\ [ Math . 2 ] & \\ ρ \frac{Du}{Dt} = - ∇ {P}_{0} + ( μ + ɛ ) ∇ D + μΔ u & ( 2 ) \\ [ Math . 3 ] & \\ ρ {T}_{0} \frac{DS}{Dt} = κΔ {T}_{0} = Φ & ( 3 ) \\ [ Math . 4 ] & \\ {P}_{0} = ρ {R}_{0} {T}_{0} & ( 4 )\end{matrix}$$

Here, ρ: density, u: velocity vector, P₀: pressure, S: entropy, μ: viscosity, ε: second viscosity, D: div u, T₀: temperature, κ: thermal conductivity, and R₀: gas constant. Furthermore, Φ in Equation (3) is a dissipation function.

By performing linear long wavelength approximation (Non Patent Document 6 and Non Patent Document 7) for Equations (1) to (3), the axial change dP/dx of the complex pressure amplitude P, the axial change dU/dx of the complex cross-section average flow velocity amplitude U, and the cross-sectional average complex temperature amplitude T in thermoacoustic engine can be obtained as in Equations (5), (6), and (7), respectively. In addition, here, as an example, Equations (5) to (7) are obtained by the linear long wavelength approximation, but the linear long wavelength approximation is not necessarily necessary, and in case of an equation that can express the thermal efficiency is obtained, it is not limited to the results of Equations (5) to (7).

$$\begin{matrix}[ Math . 5 ] & \\ \frac{dP}{dx} = - \frac{j {ωρ}_{m}}{1 - {χ}_{v}} U & ( 5 ) \\ [ Math . 6 ] & \\ \frac{dU}{dx} = - \frac{j ω}{{P}_{m}} [ 1 - ( γ - 1 ) {χ}_{α} ] P + \frac{{χ}_{α} - {χ}_{v}}{( 1 - {χ}_{v} ) ( 1 - σ )} \frac{1}{{T}_{m}} \frac{{dT}_{m}}{dx} U & ( 6 ) \\ [ Math . 7 ] & \\ T = \frac{1}{{C}_{P} {ρ}_{m}} ( 1 - {χ}_{α} ) P - ( \frac{( 1 - {χ}_{α} ) - σ ( 1 - {χ}_{v} )}{( 1 - {χ}_{v} ) ( 1 - σ )} ) \frac{1}{j ω} \frac{{dT}_{m}}{dx} U & ( 7 )\end{matrix}$$

Here, j: imaginary unit, ω: angular frequency, γ: specific heat ratio, Pₘ: mean pressure, σ: Prandtl number, C_{P}: constant pressure specific heat, ρₘ: mean density. Furthermore, χ_{α} and χᵥ are thermoacoustic functions related to thermal and viscosity that depend on the parameters related to ωτ_{α} and ωτᵥ described later. τ_{α} and τᵥ are heat relaxation time and viscosity relaxation time.

Acoustic intensity (work flux density) I and heat flux density Q can be expressed as follows in the case of oscillating flow.

$$\begin{matrix}[ Math . 8 ] & \\ I = \frac{1}{2} Re [ \tilde{P} U ] & ( 8 ) \\ [ Math . 9 ] & \\ Q = \frac{1}{2} {C}_{P} {ρ}_{m} Re [ T \tilde{U} ] - I & ( 9 )\end{matrix}$$

Here, Re [ ] indicates a real number of [ ], and ˜ indicates a complex conjugate.

In addition, the thermal efficiency η of the thermoacoustic engine 100 is expressed by following Equation (10) using the heat flux density Q and the acoustic intensity I at the axial center of the regenerator 120. Here, the work source W can be expressed by the slope (gradient) of the acoustic intensity I in the regenerator 120 as shown in Equation (11). Equations (10) and (11) can be applied not only to the flow path diameter but also to a representative length corresponding to the flow path width and the flow path diameter; for example, a circular tube, a parallel plate, a polygon, a pin array, a random flow path or a flow path in which pattern is repeated.

$$\begin{matrix}[ Math . 10 ] & \\ η = \frac{d I}{Q + \frac{d I}{2}} = \frac{Wdx}{Q + \frac{Wdx}{2}} & ( 10 ) \\ [ Math . 11 ] & \\ \frac{d l}{d x} = W = \frac{1}{2} Re [ \frac{d \tilde{P}}{dx} U ] + \frac{1}{2} Re [ \tilde{P} \frac{dU}{dx} ] & ( 11 )\end{matrix}$$

Hereinafter, Equation (10) is modified in order to determine the flow path diameter of the flow path 122 of the regenerator 120 of the thermoacoustic engine 100. Equation (10) is modified into a quadratic equation with the flow path diameter as a parameter, based on the result of component separation of the index of work source W and heat flux density Q using thermoacoustic theory as described later. Equation (10) can be applied not only to the flow path diameter but also to a representative length corresponding to the flow path width and the flow path diameter of a flow path of, for example, a circular tube, a parallel plate, a polygon, a pin array, a random flow path or a flow path in which pattern is repeated.

In this calculation example, by substituting Equations (5) to (7) into Equation (11) indicating the work source W and developing the equations, the work source W can be further separated into factors such as a component that contributes to energy conversion of the thermoacoustic engine 100 and a component that dissipates due to viscosity or heat conduction. In addition, in Q, by substituting Equations (5) to (7) into equation (9) and developing the equations, a heat flow component associated with energy conversion and a heat flow component associated with heat diffusion caused by vibration can be separated. In this development, the development was performed based on the thermoacoustic theory by Tominaga (Non Patent Document 7). Furthermore, by rewriting the equation using the relation of Equation (12), W and Q can be separated as shown in Equations (13) and (14). In the present example, W and Q are separated in order to show the case of simplification, and this separation step is not indispensable as long as the thermal efficiency can be described by an equation.

$$\begin{matrix}[ Math . 12 ] & \\ Θ = \frac{λ}{{T}_{m}} \frac{{dT}_{m}}{dx} , λ = \frac{c}{ω} , \\ \vert {z}_{n} \vert = \frac{1}{{ρ}_{m} c} \frac{\vert P \vert}{\vert U \vert} , C = \sqrt{\frac{γ {p}_{m}}{{ρ}_{m}}} , \\ {ρ}_{m} {C}_{p} = \frac{{ρ}_{m} {c}^{2}}{{T}_{m} ( γ - 1 )} & ( 12 ) \\ [ Math . 13 ] & \\ W = {W}_{v} + {W}_{p} + {W}_{prog} + {W}_{stand} \\ {W}_{v} = \frac{\vert P \vert \vert U \vert}{2} \frac{1}{λ} Im [ \frac{1}{1 - {χ}_{v}} ] \frac{1}{\vert {z}_{n} \vert} . \\ {W}_{p} = \frac{\vert P \vert \vert U \vert}{2} \frac{1}{λ} ( γ - 1 ) Im [ {χ}_{α} ] \vert {z}_{n} \vert . \\ {W}_{prog} = \frac{\vert P \vert \vert U \vert}{2} \frac{1}{λ} Re [ b ] Θcosϕ . \\ {W}_{stand} = - \frac{\vert P \vert \vert U \vert}{2} \frac{1}{λ} Im [ b ] Θsinϕ . \\ b = \frac{{χ}_{α} - {χ}_{v}}{( 1 - σ ) ( 1 - {χ}_{v} )} & ( 13 ) \\ [ Math . 14 ] & \\ Q = {Q}_{prog} + {Q}_{stand} + {Q}_{D} \\ {Q}_{prog} = - \frac{\vert P \vert \vert U \vert}{2} \frac{1}{λ} λ Re [ g ] cos ϕ . \\ {Q}_{stand} = - \frac{\vert P \vert \vert U \vert}{2} \frac{1}{λ} λ Im [ g ] sin ϕ . \\ {Q}_{D} = \frac{\vert P \vert \vert U \vert}{2} \frac{1}{λ} \frac{λ}{( γ - 1 )} Re [ \frac{1}{1 - {χ}_{v}} ] Im [ {g}_{D} ] Θ \frac{1}{\vert {z}_{n} \vert} . \\ g = \frac{{χ}_{a} - {\tilde{χ}}_{v}}{( 1 + σ ) ( 1 - {\tilde{χ}}_{v} )} \\ {g}_{D} = \frac{( {χ}_{a} - {\tilde{χ}}_{v} ) - ( 1 + σ ) {χ}_{v} + ( 1 + σ ) Re [ {χ}_{v} ]}{( 1 - Re [ {χ}_{v} ] ) ( 1 - {σ}^{2} )} & ( 14 )\end{matrix}$$

Here, Wᵥ: loss of acoustic intensity due to viscosity, Wₚ: loss of acoustic intensity due to heat diffusion, W_{prog}: energy conversion by traveling wave phase, and W_{stand}: energy conversion by standing wave phase.

Furthermore, Q_{prog}: heat flux density due to traveling wave component, Q_{stand}: heat flux density due to standing wave component, and Q_{D}: heat flux density due to heat diffusion effect due to oscillating flow.

A thermoacoustic engine with inherently high thermal efficiency is a traveling wave thermoacoustic engine that enables reversible energy conversion. In the present embodiment, the phase difference φ between P and U is assumed to be 0 in order to study a traveling wave energy conversion having high thermal efficiency. In the present embodiment, only traveling wave energy conversion is assumed, but it is possible to consider the components of W_{stand} and Q_{stand} depending on the design conditions to be implemented, and the present invention is not limited to this example. In a case of φ=0, W_{stand} and Q_{stand}, which are components related to standing waves, become 0, so that Wᵥ, Wₚ, W_{prog}, Q_{prog}, and Q_{D} are used below. Thermal efficiency equation of Equation (10) is rewritten using the length of the regenerator dx and Wᵥ, Wₚ, W_{prog}, Q_{prog}, and Q_{D} separated as described above, therefore the thermal efficiency η of the thermoacoustic engine 100 is expressed by following Equation (15).

$$\begin{matrix}[ Math . 15 ] & \\ η = ( \frac{( {W}_{v} + {W}_{p} + {W}_{prog} ) dx}{( - ( {Q}_{D} + {Q}_{prog} ) + ( {W}_{v} + {W}_{p} + {W}_{prog} ) \frac{dx}{2} )} ) & ( 15 )\end{matrix}$$

By substituting Equations (13) and (14) into Equation (15) and rearranging the equations, following Equation (16) of the thermal efficiency η can be obtained. The term included in Equation (16) is an example, and in case ofthere are other components that contribute to the energy conversion of the thermoacoustic phenomenon, these components can be incorporated as necessary. (Non Patent Documents 8 and 9) In addition, in a case where there is an unnecessary term depending on the set conditions, the term can be deleted.

$$\begin{matrix}[ Math . 16 ] & \\ η = \frac{( Im [ \frac{1}{1 - {χ}_{v}} ] \frac{1}{\vert {z}_{n} \vert} + ( γ - 1 ) Im [ {χ}_{α} ] \vert \hat{z} \vert + Re [ b ] Θ ) dx}{\begin{matrix}- ( \frac{λ}{( γ - 1 )} Re [ \frac{1}{1 - {χ}_{v}} ] Im [ {g}_{D} ] Θ \frac{1}{\vert {z}_{n} \vert} - λ Re [ g ] ) + \\ ( Im [ \frac{1}{1 - {χ}_{v}} ] \frac{1}{\vert {z}_{n} \vert} + ( γ - 1 ) Im [ {χ}_{α} ] \vert \hat{z} \vert + Re [ b ] Θ ) \frac{dx}{2}\end{matrix}} & ( 16 )\end{matrix}$$

Step of preparing Equation Showing Shape of Flow Path of Regenerator

Here, the parameter depending on the flow path diameter is a term including χ_{υ} and χ_{α}. An equation is used to express the term including χ_{υ} and χ_{α} by the flow path diameter of the flow path 122. In addition, this equation differs depending on the shape of the flow path 122. In the following description, the optimization method will be described using a circular tube or a parallel plate as an example, but by using an equation corresponding to the shape of the flow path 122 of the regenerator 120 to be used, it is possible to obtain not only the circular tube and the parallel plate but also the flow path diameter of the flow path 122 and a representative length corresponding thereto.

[Case of Circular Tube Flow Path]

First, an example of an equation showing the shape of the flow path in the case of a circular tube flow path is shown. In a situation where the flow path diameter of the flow path 122 of the regenerator 120 is sufficiently small, the following relationship can be used for the circular tube flow path.

$$\begin{matrix}[ Math . 17 ] & \\ Im [ \frac{1}{1 - {χ}_{v}} ] = - 4 σ \frac{1}{ω {τ}_{α}} \\ Im [ {χ}_{α} ] = - \frac{1}{4} {ωτ}_{α} \\ Re [ b ] = 1 \\ Re [ \frac{1}{1 - {χ}_{v}} ] = \frac{4}{3} \\ Im [ {g}_{D} ] = \frac{11}{32} ( 1 - {σ}^{2} ) ω {τ}_{α} \\ Re [ g ] = 1 & ( 17 )\end{matrix}$$

[Case of Parallel Plate]

Next, an example of an equation showing the shape of the flow path in the case where the flow path 122 of the regenerator 120 is formed in the parallel plate is shown. In a case where the flow path 122 of the regenerator 120 is formed in the parallel plate and the flow path diameter (=2r: refer to FIG. 3) of the parallel plate is sufficiently small, the following relationship can be used.

$$\begin{matrix}[ Math . 18 ] & \\ Im [ \frac{1}{1 - {χ}_{v}} ] = - 4 σ \frac{1}{ω {τ}_{α}} \\ Im [ {χ}_{α} ] = - \frac{1}{4} {ωτ}_{a} \\ Re [ b ] = 1 \\ Re [ \frac{1}{1 - {χ}_{v}} ] = \frac{4}{3} \\ Im [ {g}_{D} ] = \frac{11}{32} ( 1 - {σ}^{2} ) ω {τ}_{α} \\ Re [ g ] = 1 & ( 18 )\end{matrix}$$

By substituting the relationship between Equations (17) and (18) into Equation (16), the thermal efficiency equation can be rewritten into a form corresponding to the flow path diameter.

### Step of Selecting any one of Parameters of Flow Path Diameter (Equivalent Flow Path Diameter), Frequency, Temperature Gradient, and Specific Acoustic Impedance

Here, since the flow path diameter of the regenerator is the design target, the calculation is performed for the parameter ωτ_{α}. In a case where a design related to any one parameter of the frequency, the temperature gradient, and the specific acoustic impedance is performed in addition to the flow path diameter, the calculation may be performed for the selected parameter such as parameters λ and Θ in case of the frequency is the design target, parameter Θ in case of the temperature gradient is the design target, and parameter zₙ in case of the specific acoustic impedance is the design target.

### Step of Creating Equation Related to Selected Parameter based on Equation Showing Thermal Efficiency and Equation Showing Shape of Flow Path of Regenerator

Here, using the case of the circular tube flow path and the parallel plate flow path shown in Equations (17) to (18) as an example, an equation is created related to the flow path diameter based on the equation showing the thermal efficiency and the equation showing the shape of the flow path. As the flow path shape, a flow path such as a polygon, a pin array, or a random flow path or a flow path in which pattern is repeated can be used, and the flow path shape is not limited thereto as long as the shape can be expressed by an equation.

[Case of Circular Tube]

In the case of a circular tube flow path, by substituting Equation (17) into Equation (16), the thermal efficiency is expressed as following Equation (19).

$$\begin{matrix}[ Math . 19 ] & \\ η = \frac{( - 4 σ \frac{1}{\vert {z}_{n} \vert {ωτ}_{α}} - \frac{1}{4} ( γ - 1 ) \vert {z}_{n} \vert {ωτ}_{α} + Θ ) dx}{\begin{matrix}\vert ( \frac{λ}{( γ - 1 )} \frac{11}{24} Θ \frac{1}{\vert {z}_{n} \vert} ω {τ}_{α} + λ ) + \\ ( - 4 σ \frac{1}{\vert {z}_{n} \vert {ωτ}_{α}} - \frac{1}{4} ( γ - 1 ) \vert {z}_{n} \vert {ωτ}_{a} + Θ ) \frac{d x}{2} \vert\end{matrix}} & ( 19 )\end{matrix}$$

[Case of Simply Expressing Circular Tube]

In addition, since Wₚ in Equation (15) is sufficiently smaller than Wᵥ, W_{prog}, Q_{D}, and Q_{prog}, it is possible to simply obtain ωτ_{α} based on Equation (20) shown below by ignoring Wₚ.

$$\begin{matrix}[ Math . 20 ] & \\ η = ( \frac{( {W}_{υ} + {W}_{prog} ) d x}{( - ( {Q}_{D} + {Q}_{prog} ) )} ) = \frac{( - 4 σ \frac{1}{\vert {z}_{n} \vert {ωτ}_{α}} + Θ ) dx}{\vert ( \frac{λ}{( γ - 1 )} \frac{11}{24} Θ \frac{1}{\vert {z}_{n} \vert} ω {τ}_{α} + λ ) + ( - 4 σ \frac{1}{\vert {z}_{n} \vert {ωτ}_{a}} + Θ ) \frac{d x}{2} \vert} & ( 20 )\end{matrix}$$

[Case of Parallel Plate]

In the case of a parallel plate, by substituting Equation (18) into Equation (16), the thermal efficiency is expressed as following Equation (21).

$$\begin{matrix}[ Math . 21 ] & \\ η = \frac{( - \frac{3}{2} σ \frac{1}{\vert {z}_{n} \vert {ωτ}_{α}} - \frac{2}{3} ( γ - 1 ) \vert {z}_{n} \vert {ωτ}_{α} + Θ ) dx}{\begin{matrix}\vert ( \frac{λ}{( γ - 1 )} \frac{6}{5} \frac{17}{21} Θ \frac{1}{\vert {z}_{n} \vert} ω {τ}_{α} + λ ) + \\ ( - \frac{3}{2} σ \frac{1}{\vert {z}_{n} \vert {ωτ}_{α}} - \frac{2}{3} ( γ - 1 ) \vert {z}_{n} \vert {ωτ}_{α} + Θ ) \frac{d x}{2} \vert\end{matrix}} & ( 21 )\end{matrix}$$

[Case of Simply Expressing Parallel plate]

In addition, similarly to the case of the circular tube, in the case of the parallel plate, since Wₚ in Equation (15) is sufficiently smaller than Wᵥ, W_{prog}, Q_{D}, and Q_{prog}, it is possible to simply obtain ωτ_{α} based on Equation (22) shown below by ignoring Wₚ.

$$\begin{matrix}[ Math . 22 ] & \\ η = \frac{( - \frac{3}{2} σ \frac{1}{\vert {z}_{n} \vert {ωτ}_{α}} + Θ ) dx}{\vert ( \frac{λ}{( γ - 1 )} \frac{6}{5} \frac{17}{21} Θ \frac{1}{\vert {z}_{n} \vert} ω {τ}_{α} + λ ) + ( - \frac{3}{2} σ \frac{1}{\vert {z}_{n} \vert {ωτ}_{α}} + Θ ) \frac{d x}{2} \vert} & ( 22 )\end{matrix}$$

### Step of Calculating Value of selected Parameter Maximizing Thermal Efficiency based on Equation related to Selected Parameter by Applying a Plurality of Design Values other than Selected Parameter related to Energy Conversion Device which is Design Target

[Case of Deriving Quadratic Equation]

Here, as an example, the value that maximizes the thermal efficiency is calculated in a case where the selection parameter is the flow path diameter. As an example, the thermal efficiency equation shown in Equations (19), (20), (21), and (22) is in the form of a quadratic equation with respect to the dimensionless parameter ωτ_{α} (τ_{α}: heat relaxation time, refer to Equation (27)) including the parameter of the flow path diameter. Therefore, it is possible to uniquely obtain ωτ_{α} that maximizes the thermal efficiency η by modifying ωτ_{α} (=X) into the form of Equation (23) with a predetermined variable and differentiating ωτ_{α} (=X) to obtain the extremum.

As an example, the calculation method in a case where the parameter is a quadratic equation and the flow path diameter is set, the example in the case of a circular tube, and the example in the case of a parallel plate are shown, and the equation may be a cubic or higher equation depending on the equation of the fluid used or the parameters selected. At this time, there are a plurality of conditions in which the derivative obtained by differentiation is 0, and the selected parameter may be obtained by selecting the value that maximizes the thermal efficiency among these conditions, and is not limited to the example shown below.

$$\begin{matrix}[ Math . 23 ] & \\ η = \frac{( \frac{A}{X} + B X + C )}{\vert ( DX + E ) + ( \frac{A}{2 X} + \frac{B}{2} X + \frac{C}{2} ) \vert} & ( 23 )\end{matrix}$$

The equation (24) related to X is obtained by rearranging the derivatives based on the condition that the derivative obtained by differentiating Equation (23) becomes 0.

$$\begin{matrix}[ Math . 24 ] & \\ {X}^{2} + \frac{- 2 A D}{( C D - B E )} X + \frac{A E}{( C D - B E )} = 0 & ( 24 )\end{matrix}$$

Since Equation (24) is a quadratic equation related to X (=ωτ_{α}), Equation (25) is obtained by finding the solution.

$$\begin{matrix}[ Math . 25 ] & \\ X = \frac{1}{2} ( \frac{- 2 A D}{( C D - B E )} \pm \sqrt{{( \frac{- 2 A D}{( C D - B E )} )}^{2} - 4 \frac{A E}{( C D - B E )}} ) = 0 & ( 25 )\end{matrix}$$

[Case of Circular Tube]

In a case where the flow path diameter is calculated for a circular tube, by returning the coefficient of Equation (21) to Equation (25) and rearranging the equation, wm can be expressed by following Equation (26).

$$\begin{matrix}[ Math . 26 ] & \\ ω {τ}_{α} = \frac{44}{6} \frac{σ}{{\vert {z}_{n} \vert}^{2}} \frac{Θ}{( γ - 1 )} \frac{1}{Y} + \sqrt{{( \frac{44}{6} \frac{σ}{{\vert {z}_{n} \vert}^{2}} \frac{Θ}{( γ - 1 )} \frac{1}{{Y}^{2}} )}^{2} + \frac{16 σ}{\vert {z}_{n} \vert} \frac{1}{Y}} & ( 26 ) \\ Y = \frac{11}{6} \frac{{Θ}^{2}}{( γ - 1 )} \frac{1}{\vert {z}_{n} \vert} + ( γ - 1 ) \vert {z}_{n} \vert & \end{matrix}$$

In addition, the relationship between ωτ_{α} and the flow path radius r is expressed by following Equation (27).

$$\begin{matrix}[ Math . 27 ] & \\ ω {τ}_{α} = ω \frac{{r}^{2}}{2 α} & ( 27 )\end{matrix}$$

In case of Equation (26) is converted into the form of r, r is expressed as Equation (28).

$$\begin{matrix}[ Math . 28 ] & \\ r = \sqrt{\frac{2 α}{ω} ( \frac{44}{6} \frac{σ}{{\vert {z}_{n} \vert}^{2}} \frac{θ}{( γ - 1 )} \frac{1}{Y} + \sqrt{{( \frac{44}{6} \frac{σ}{{\vert {z}_{n} \vert}^{2}} \frac{θ}{( γ - 1 )} \frac{1}{Y} )}^{2} + \frac{16 σ}{\vert {z}_{n} \vert} \frac{1}{Y}} )} & ( 28 )\end{matrix}$$

[Case of Simply Expressing Circular Tube]

In a case where the flow path diameter is simply calculated for a circular tube, by setting B=0 in Equation (25) to correspond to Equation (20), and substituting the coefficient of Equation (20) to rearrange the equation, ωτ_{α} can be expressed by the following Equation (29).

$$\begin{matrix}[ Math . 29 ] & \\ ω {τ}_{a} = \frac{4 σ}{Θ \vert {z}_{n} \vert} + \frac{4}{Θ} \sqrt{\frac{{σ}^{2}}{{\vert {z}_{n} \vert}^{2}} + \frac{6 ( γ - 1 ) σ}{11}} & ( 29 )\end{matrix}$$

In case of converted into the form of r using Equation (27), r is expressed as Equation (30).

$$\begin{matrix}[ Math . 30 ] & \\ r = \sqrt{\frac{2 α}{ω} ( \frac{4 σ}{Θ \vert {z}_{n} \vert} + \frac{4}{Θ} \sqrt{\frac{{σ}^{2}}{{\vert {z}_{n} \vert}^{2}} + \frac{6 ( γ - 1 ) σ}{11}} )} & ( 30 )\end{matrix}$$

As described above, according to the design method of the thermoacoustic engine, it is possible to uniquely obtain the flow path diameter of the flow path 122 of the regenerator 120, which is the maximum point of thermal efficiency.

[Case of Expressing Parallel Plate]

In a case where the flow path diameter is calculated for a parallel plate, by returning the coefficient of Equation (21) to Equation (25) and rearranging the equation, wm can be expressed by following Equation (31).

$$\begin{matrix}[ Math . 31 ] & \\ ω {τ}_{a} = \frac{153}{70} \frac{σ}{{\vert {z}_{n} \vert}^{2}} \frac{Θ}{( γ - 1 )} \frac{1}{J} + \sqrt{{( \frac{153}{70} \frac{σ}{{\vert {z}_{n} \vert}^{2}} \frac{Θ}{( γ - 1 )} \frac{1}{J} )}^{2} + \frac{9}{4} \frac{σ}{\vert {z}_{n} \vert} \frac{1}{J}} \\ J = \frac{51}{35} \frac{{Θ}^{2}}{( γ - 1 )} \frac{1}{\vert {z}_{n} \vert} + ( γ - 1 ) \vert {z}_{n} \vert & ( 31 )\end{matrix}$$

Using Equation (27), the radius (=r) of the flow path is expressed as in Equation (32).

$$\begin{matrix}[ Math . 32 ] & \\ r = \sqrt{\frac{2 α}{ω} ( \frac{153}{70} \frac{σ}{{\vert {z}_{n} \vert}^{2}} \frac{Θ}{( γ - 1 )} \frac{1}{J} + \sqrt{{( \frac{153}{70} \frac{σ}{{\vert {z}_{n} \vert}^{2}} \frac{Θ}{( γ - 1 )} \frac{1}{J} )}^{2} + \frac{9}{4} \frac{σ}{\vert {z}_{n} \vert} \frac{1}{J}} )} & ( 32 )\end{matrix}$$

[Case of Simply Expressing Parallel Plate]

In a case of simply expressing the case of a parallel plate, the result obtained by setting B=0 in Equation (25) to correspond to Equation (22), and substituting the coefficient of Equation (22) in the same manner as the case of the circular tube is expressed as following Equation (33), and in case of converted into the shape of the radius of the flow path 122 using Equation (27), it is expressed as Equation (34).

$$\begin{matrix}[ Math . 33 ] & \\ ω {τ}_{a} = \frac{3}{2} \frac{σ}{Θ \vert {z}_{n} \vert} + \frac{3}{2} \frac{1}{Θ} \sqrt{\frac{{σ}^{2}}{{\vert {z}_{n} \vert}^{2}} + \frac{31}{51} ( γ - 1 ) σ} & ( 33 ) \\ [ Math . 34 ] & \\ r = \sqrt{\frac{2 α}{ω} ( \frac{3}{2} \frac{σ}{Θ \vert {z}_{n} \vert} + \frac{3}{2} \frac{1}{Θ} \sqrt{\frac{{σ}^{2}}{{\vert {z}_{n} \vert}^{2}} + \frac{31}{51} ( γ - 1 ) σ} )} & ( 34 )\end{matrix}$$

From the above equations, there are four parameters of (i) flow path diameter, (ii) frequency, (iii) temperature gradient, and (iv) specific acoustic impedance as a parameter that can be selected. In the development of the above equation, the flow path diameter of (i) was determined by setting (ii) to (iv), but in case of three of the four parameters (i) to (iv) are set, the remaining one parameter can be determined so as to maximize the thermal efficiency. Therefore, according to the design method of the thermoacoustic engine, not only the flow path diameter that maximizes the thermal efficiency of the regenerator 120 but also any of the frequency, the temperature gradient, and the specific acoustic impedance can be uniquely determined.

[Calculation Example]

An example of actual calculation using the above equations is shown.

FIG. 6 shows the physical property values and the like commonly used in the case of the circular tube and the case of the parallel plate. In this calculation example, in order to determine the optimum flow path radius r, the result of calculating the thermal efficiency while changing r and the result of obtaining r by the optimization method according to the present proposed method are compared.

In the numerical calculation of thermal efficiency, Equation (16) was used for both the cases of the circular tube and the parallel plate. The optimization of r was calculated using Equations (28) and (30) in the case of the circular tube and using equations (32) and (34) in the case of the parallel plate.

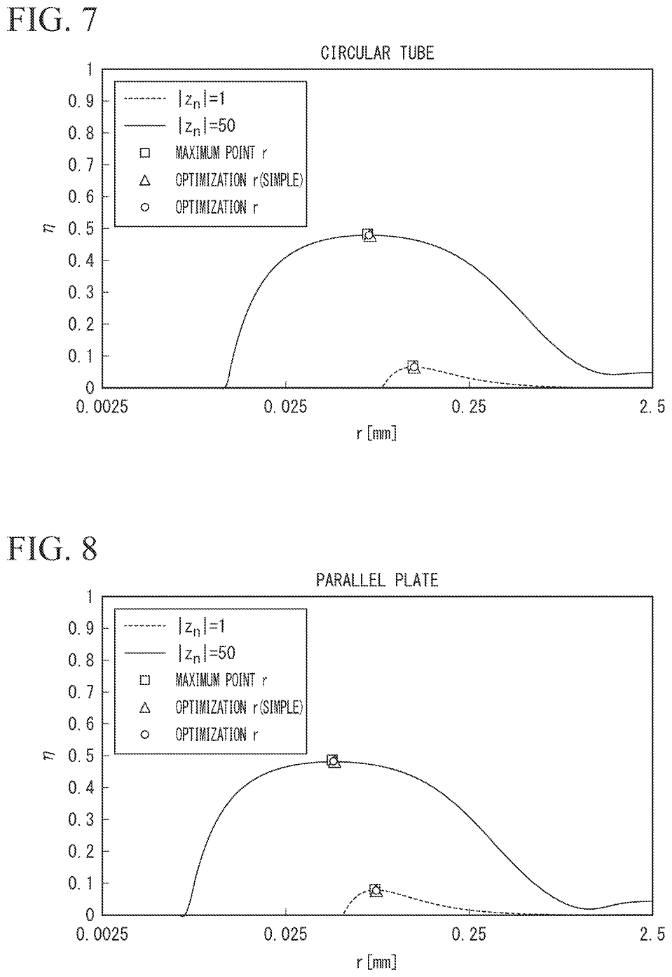

FIG. 7 shows the calculation result in the case of the circular tube, and FIG. 8 shows the calculation result of the parallel plate. In the figure, r is shown on the horizontal axis, and thermal efficiency is shown on the vertical axis. In the figure, the line shows the result of numerical calculation by gradually changing r based on Equation (16). The optimum point of the radius r of the flow path diameter that maximizes the thermal efficiency in this numerical calculation is indicated by a square point.

In addition, in the figure, the optimum point of the radius r of the flow path diameter that maximizes the thermal efficiency simply obtained based on Equation (30) or (34) is indicated by a triangular point. In addition, the optimum point of the radius r of the flow path diameter that maximizes the thermal efficiency obtained based on Equation (28) or (32) is indicated by a circle. In addition, the difference in line type indicates the difference in |zₙ|.

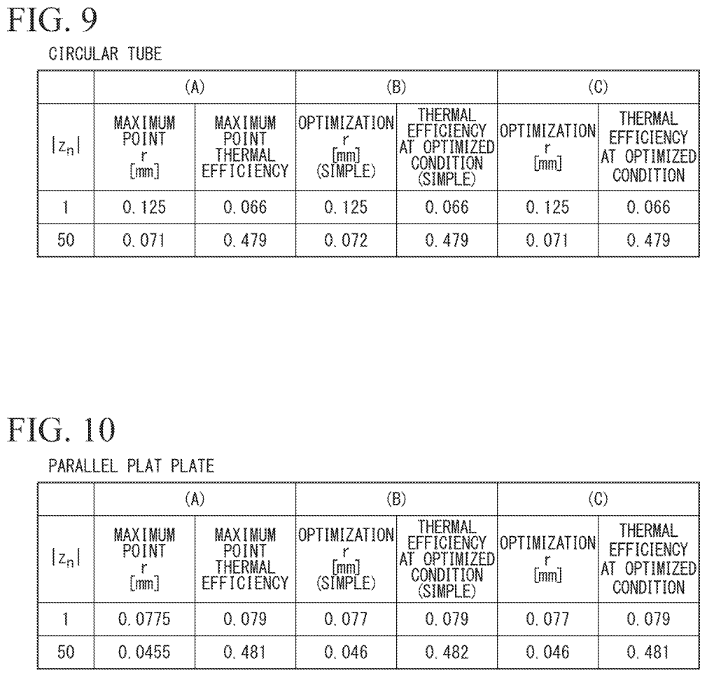

FIG. 9 shows a numerical value at the maximum thermal efficiency point in the case of the circular tube. FIG. 10 shows a numerical value at the maximum thermal efficiency point in the case of the parallel plate. (A) in each figure shows the radius r of the flow path diameter that maximizes the thermal efficiency of the curve drawn based on the numerical calculation based on Equation (16) and the value of the thermal efficiency η at that time.

In addition, (B) in each figure shows the radius r of the flow path diameter optimized so as to maximize the thermal efficiency simply obtained based on Equation (30) or (34), and the value of the thermal efficiency η0 obtained by Equation (19) or (21) using r at that time. In addition, (C) in each figure shows the radius r of the flow path diameter optimized so as to maximize the thermal efficiency obtained by Equation (28) or (32), and the value of the thermal efficiency η obtained by Equations (20) and (22).

As shown in FIGS. 7 and 8, in case of |zₙ| is changed, the maximum point of the thermal efficiency increases and r, which maximizes the thermal efficiency, also changes. In addition, the optimum point of r obtained by using the optimization method according to the embodiment coincided with the maximum point of the thermal efficiency η at each |zₙ|.

As shown in FIGS. 9 and 10, according to the design method of the thermoacoustic engine, the calculation result of the flow path diameter that maximizes the thermal efficiency η based on Equations (30) and (34) that are simply optimized coincides well with the case in case of compared by value for each |zₙ|. As described above, according to the design method of the thermoacoustic engine, r in case of the thermal efficiency is maximized can be easily obtained.

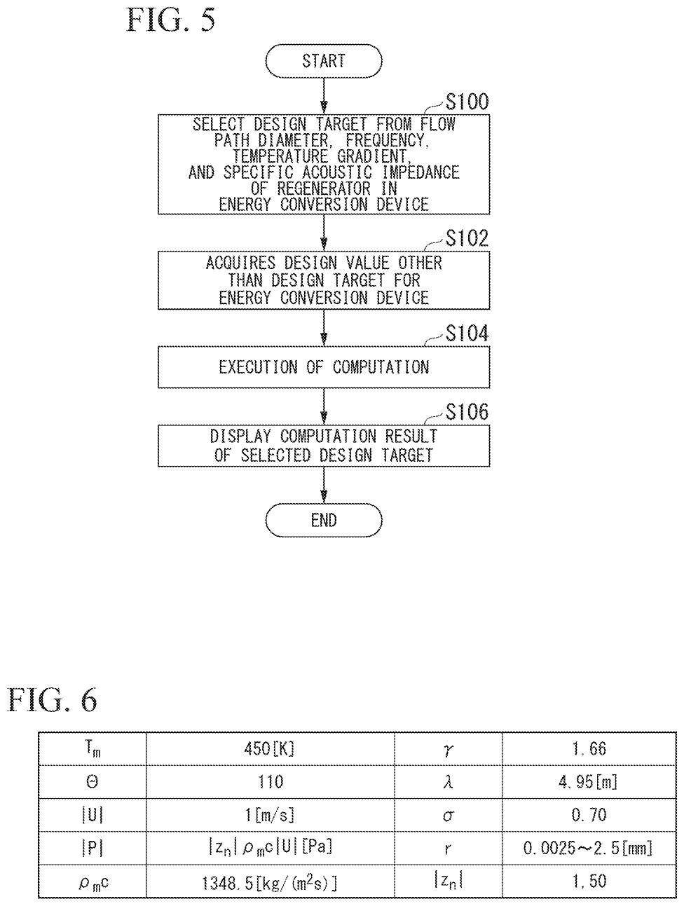

The design method of the thermoacoustic engine described above is used to support the design of the thermoacoustic engine by using the design device 1 (refer to FIG. 1). FIG. 5 shows a flow of processing executed in the design device 1. The designer selects one design value for which he/she wants to obtain a value from the flow path diameter, the frequency, the temperature gradient, and the specific acoustic impedance of the regenerator in the energy conversion device.

A plurality of design values (parameters) other than the design target selected from the flow path diameter, the frequency, the temperature gradient, and the specific acoustic impedance of the regenerator in the energy conversion device are input to the input unit 10 (Step S100). The input information on the plurality of design values is temporarily stored in the storage unit 30.

The computation unit 20 acquires the plurality of design values other than the parameters of the design target for the energy conversion device from the input unit 10 (Step S102). The computation unit 20 creates an equation related to the selected parameter of the design target based on the acquired plurality of design values, applies a plurality of design values other than the selected parameters related to the energy conversion device which is the design target, and calculates the value of the selected parameter that maximizes the thermal efficiency based on the equation related to the selected parameter (Step S104). The equations related to the selected parameters of the design target may be created each time, or the equations created in advance may be stored in the storage unit 30. The display unit 40 outputs the calculation result calculated by the computation unit 20 (Step S106). At this time, in a case where the design targets are independently designed in parallel, one or more design targets may be selected.

Continuously, in a case where the energy conversion device is designed, the process returns to the selection of the design target from the flow path diameter, the frequency, the temperature gradient, and the specific acoustic impedance of the regenerator in the first energy conversion device. In a case where the design of the energy conversion device is ended, the program is ended. Here, continuously, in a case where the energy conversion device is designed, the process may return to the input of the design value of the energy conversion device.

As described above, according to the design method of the thermoacoustic engine, it is possible to uniquely determine the flow path diameter, the frequency, the temperature gradient, and the specific acoustic impedance of the regenerator that can maximize the thermal efficiency under the conditions required by the designer, without performing the enormous calculations and experiments that have been performed in the related art. In addition, according to the design method of the thermoacoustic engine, it is possible to consider in advance whether the optimum flow path diameter of the regenerator can be manufactured, and it is possible to consider changes in specifications during design, so that it is possible to reduce the time and cost required for design and development.

As described above, the thermoacoustic phenomenon has been described as an example, and the present invention is not limited to the thermoacoustic engine based on the thermoacoustic phenomenon, and can be applied to an energy conversion device such as a Stirling engine, a pulse tube refrigerator, a GM refrigerator, a Stirling cooler, a heat pipe, a thermoacoustic engine with a regenerator that utilizes an oscillating flow of fluid.

### REFERENCE SIGNS LIST

1: design device

10: input unit

20: computation unit

30: storage unit

40: display unit

100: thermoacoustic engine

110: pipeline

120: regenerator

122: flow path

What is claimed is:

1. A design method for an energy conversion device using an oscillating flow of a working fluid enclosed inside the energy conversion device, the method causing a design device to execute processing comprising:
a step of creating an equation showing a thermal efficiency with respect to a predetermined variable including a flow path diameter (equivalent flow path diameter), a frequency, a temperature gradient, and specific acoustic impedance of a flow path in a regenerator performing energy conversion based on an equation of fluid related to the oscillating flow;
a step of selecting any one input parameter of the flow path diameter (equivalent flow path diameter), the frequency, the temperature gradient, and the specific acoustic impedance;
a step of creating an equation related to the selected parameter based on the equation showing the thermal efficiency and an equation showing a shape of the flow path of the regenerator; and
a step of uniquely calculating a value of the selected parameter maximizing the thermal efficiency based on the equation related to the selected parameter by applying a plurality of design values other than the selected parameter related to the energy conversion device which is a design target.

2. The design method according to claim 1, wherein
the equation related to the selected parameter is a quadratic or higher equation, and
the equation related to the selected parameter is created based on a condition that a derivative obtained by differentiating the quadratic or higher equation with respect to the predetermined variable so as to maximize the thermal efficiency is 0.

3. The design method according to claim 1, wherein
the working fluid is a gas and/or a liquid, and
the equation of the fluid includes an equation related to the gas and/or the liquid.

4. The design method according to claim 1, wherein
the equation showing the shape of the flow path is set for any one of flow paths formed of a circular tube, a parallel plate, a polygon, and a pin array.

5. The design method according to claim 1, wherein
the equation showing the shape of the flow path is set for any one of flow paths formed of a foamed metal, a steel wool, filled metal powders, and a rounded film with irregularities.

6. The design method according to claim 1, wherein
the equation showing the shape of the flow path is set for a flow path formed by laminating thin mesh plates having different flow path diameters (flow path widths), flow path shapes, and thicknesses.

7. The design method according to claim 1, further comprising:
a step of separating a work source into a component contributing to energy conversion and a component dissipative due to factors including viscosity and heat conduction in the regenerator based on a thermoacoustic theory in the step of creating the equation showing the thermal efficiency; and
a step of adding or deleting a component corresponding to the energy conversion device applied by a step of separating a heat flux density into a component associated with energy conversion of the regenerator and a component of heat diffusion generated by the oscillating flow.

8. The design method according to claim 1, wherein
the equation of the fluid is set to an equation related to traveling wave energy conversion.

9. A design device of an energy conversion device using an oscillating flow of a working fluid enclosed inside the energy conversion device, the device comprising:
an input device configured to perform input to select any one of the parameters of a flow path diameter (equivalent flow path diameter), a frequency, a temperature gradient, and specific acoustic impedance of a flow path in a regenerator performing energy conversion; and
a computation device configured to create an equation showing a thermal efficiency of a predetermined variable including the flow path diameter (equivalent flow path diameter), the frequency, the temperature gradient, and the specific acoustic impedance based on an equation of fluid related to the oscillating flow, creates an equation related to the parameter selected by input of the input device based on the equation showing the thermal efficiency and an equation showing a shape of the flow path of the regenerator; and uniquely calculates a value of the selected parameter maximizing the thermal efficiency based on the equation related to the selected parameter by applying a plurality of design values other than the selected parameter related to the energy conversion device which is a design target.

10. A non-transitory computer-readable recording medium recording a program executed by a design device of an energy conversion device using an oscillating flow of a working fluid enclosed inside the energy conversion device, the program is configured to cause a computer to:
create an equation showing a thermal efficiency with respect to a predetermined variable including a flow path diameter (equivalent flow path diameter), a frequency, a temperature gradient, and specific acoustic impedance of a flow path in a regenerator that performs energy conversion based on an equation of fluid related to the oscillating flow;
select any one parameter of the flow path diameter (equivalent flow path diameter), the frequency, the temperature gradient, and the specific acoustic impedance, based on input;
create an equation related to the selected parameter based on the equation showing the thermal efficiency and an equation showing a shape of the flow path of the regenerator; and
uniquely calculate a value of the selected parameter maximizing the thermal efficiency based on the equation related to the selected parameter by applying a plurality of design values other than the selected parameter related to the energy conversion device which is a design target.
